(19) United States
(12) Patent Application Publication
(10) Pub. No.: US 2026/0059810 A1
(43) Pub. Date: Feb. 26, 2026

(54) SEMICONDUCTOR STRUCTURE

(71) Applicant: Fujian Jinhua Integrated Circuit Co., Ltd., Fujian (CN)

(72) Inventor: Daochu WU, Fujian (CN)

(73) Assignee: Fujian Jinhua Integrated Circuit Co., Ltd., Fujian (CN)

(21) Appl. No.: 19/284,699

(22) Filed: Jul. 30, 2025

(30) Foreign Application Priority Data
Aug. 22, 2024 (CN) 202411162631.3

(51) Int. Cl. H10D 62/10; H10B 12/00; H10D 64/27; H10D 64/66

(52) U.S. Cl. CPC H10D 62/115; H10D 62/102; H10D 64/513; H10D 64/518; H10D 64/661; H10D 64/669; H10B 12/053; H10B 12/315

(57) ABSTRACT

The present application provides a semiconductor structure, which relates to the field of semiconductor technology and is used to solve the problem that the performance of semiconductor structure is difficult to improve. The semiconductor structure includes a substrate, including an isolation structure and an active region defined by the isolation structure; the gate trench disposed in the substrate; the gate electrode located in the gate trench and including a gate semiconductor layer; voids located in the gate trench, at least one of the voids is connected to the gate semiconductor layer. In the present application, by disposing the voids in the gate trench and enabling at least one of the voids to connect with the gate semiconductor layer, the small size of the semiconductor structure can be ensured, while the performance of the semiconductor structure can be improved.

### CROSS-REFERENCE TO RELATED APPLICATION

This application claims priority to Chinese Patent Application No. 202411162631.3, filed on Aug. 22, 2024, which is hereby incorporated by reference in its entirety.

### TECHNICAL FIELD

The present application relates to the field of semiconductor technology, and, in particular, to a semiconductor structure.

### BACKGROUND

With the development of semiconductor technology, semiconductor integrated circuits tend to be smaller-size design and higher-density layout; and for smaller and smaller semiconductor structures, it is more and more difficult to further reduce the size of semiconductor structures and ensure their performance.

In related technologies, since the process of manufacturing the traditional planar metal-oxide-semiconductor (MOS) transistor is difficult to achieve persistent shrink, how to improve the traditional planar MOS transistor, thereby reducing the geometric size of MOS transistor and/or improving the performance of transistor component, has become an urgent technical problem.

### SUMMARY

In view of the above problems, embodiments of the present application provide a semiconductor structure for reducing the geometric size of the semiconductor structure, while improving the performance of the semiconductor structure.

In order to achieve the above-mentioned purposes, embodiments of the present application provide the following technical solutions.

Embodiments of the present application provide a semiconductor structure, including a substrate, a gate trench, a gate electrode, and voids. The substrate includes an isolation structure and an active region defined by the isolation structure; the gate trench is disposed in the substrate; the gate electrode is disposed in the gate trench, and the gate electrode includes a gate semiconductor layer; the voids are located in the gate trench, and at least one of the voids is connected to the gate semiconductor layer.

In addition to the technical problems solved by embodiments of the present application, the technical features constituting the technical solutions, and the beneficial effects brought about by the technical features of these technical solutions as described above, other technical problems that can be solved by the semiconductor structure provided by the embodiments of the present application, other technical features contained in the technical solutions, and the beneficial effects brought about by these technical features, will be further described in detail in specific implementations.

### BRIEF DESCRIPTION OF DRAWINGS

To more clearly illustrate the technical solutions in embodiments of the present application, a brief introduction will be made below to the accompanying drawings required for the description of embodiments. Obviously, the accompanying drawings in the description below are some embodiments of the present application. For persons of ordinary skill in the art, other accompanying drawings can also be obtained from these accompanying drawings without creative labor.

FIG. 1 is a schematic top view of a semiconductor structure provided by an embodiment of the present application.

FIG. 2 is a partially schematic view of a first structure of a semiconductor structure along a line A-A′ of FIG. 1.

FIG. 3 is a partially schematic view of a second structure of a semiconductor structure along a line A-A′ of FIG. 1.

FIG. 4 is a partially schematic view of a third structure of a semiconductor structure along a line A-A′ of FIG. 1.

FIG. 5 is a partially schematic view of a fourth structure of a semiconductor structure along a line A-A′ of FIG. 1.

FIG. 6 is a partially schematic view of a semiconductor structure along a line B-B′ of FIG. 1 from another perspective.

FIGS. 7 to 12 are schematic top views showing a method for manufacturing a semiconductor structure according to an embodiment of the present application conception.

### DESCRIPTION OF EMBODIMENTS

With the development of science and technology, semiconductor integrated circuits tend to be smaller-size design and higher-density layout; and for smaller and smaller semiconductor structures, it is more and more difficult to further reduce the size of semiconductor structures and ensure their performance. In related technologies, in the preparation process of MOS transistors, there is a problem of adhesion between different materials, resulting in inevitable void in the semiconductor structure. However, the location of the void is very important, the performance of the semiconductor device may be affected in some locations and the performance of the semiconductor device may be affected little in other locations.

Based on the above-mentioned problems, embodiments of the present application provide a semiconductor structure; by disposing voids in a gate trench and enabling at least one void to connect with a gate semiconductor layer, the small size of the semiconductor structure can be ensured, while the performance of the semiconductor structure can be improved.

To make the above-mentioned purposes, characteristics and advantages of embodiments of the present application more obvious and understandable, the technical solution in embodiments of the present application will be clearly and described completely in combination with the accompanying drawings in embodiments of the present application. Clearly, embodiments described are only a part of embodiments of the present application and not all of the embodiments. Based on embodiments in the present application, all other embodiments obtained by a person of ordinary skill in the art without creative labor shall fall within the protection scope of the present application.

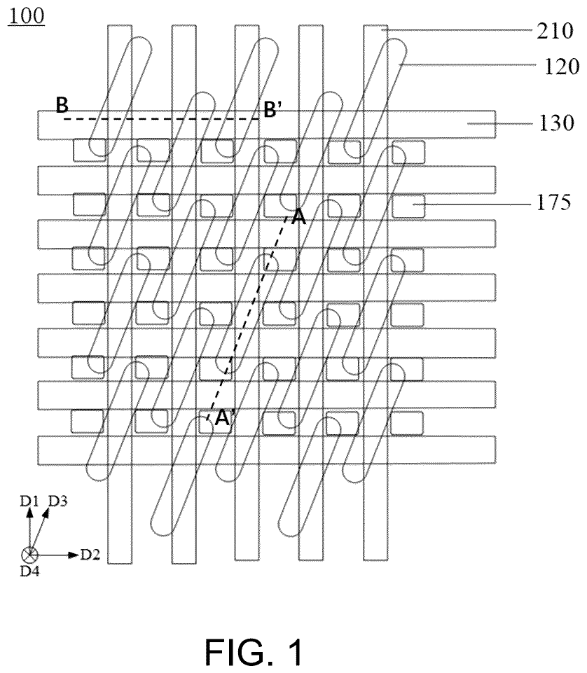

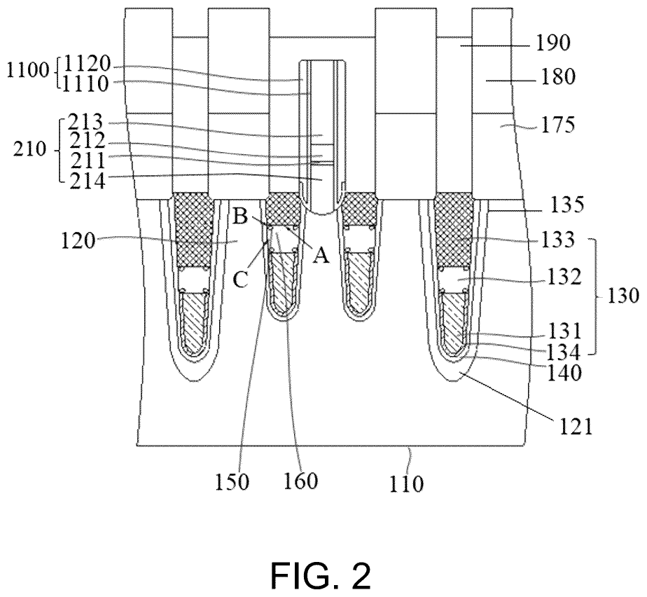

For ease of illustration and assistance in understanding of the semiconductor structure provided in the present application, please refer to FIGS. 1 and 2, which show a spatial reference direction, such as a first direction D1, a second direction D2, a third direction D3, and a fourth direction D4. Where, the first direction D1, the second direction D2 and the third direction D3 are roughly parallel to a surface of a substrate 110, and the fourth direction D4 is roughly perpendicular to the surface of the substrate 110. Here, the fourth direction D4 may also be referred as a vertical direction, and the first direction D1, the second direction D2, and the third direction D3 may also be referred as a horizontal direction.

The overall configuration of a semiconductor structure 100 is illustrated below in conjunction with the accompanying drawings.

As shown in FIGS. 1 and 2, the semiconductor structure includes a substrate 110, including an isolation structure 121 and an active region 120 defined by the isolation structure 121. In addition, a plurality of gate electrodes 130 are disposed in the substrate 110, and span the active region 120 and the isolation structure 121; and a plurality of bit lines 210 are located above the gate electrodes 130. Each gate electrode 130 can be extended along the second direction D2, the plurality of gate electrodes 130 can be arranged at intervals in the first direction D1, and the plurality of gate electrodes 130 can be arranged at a same interval in the first direction D1. The second direction D2 may be intersected with the first direction D1. Exemplarily, in the same plane, the second direction D2 may be perpendicular to the first direction D1. A width of the gate electrode 130 or the void between the adjacent gate electrodes 130 may be determined according to the actual needs. Correspondingly, each bit line 210 may be extended in the first direction D1, and the plurality of bit lines 210 may be arranged at intervals in the second direction D2. Exemplarily, the plurality of bit lines 210 may be arranged at a same interval in the second direction D2. A width of the bit line 210 or the void between the bit lines 210 may be determined according to the actual needs.

As shown in FIGS. 1 and 2, the active region 120 is defined by the isolation structure 121 on the substrate 110, and the active region 120 may be extended along the third direction D3. The third direction D3 may be a direction different from the first direction D1 and the second direction D2, and located in the same plane as the first direction D1 and the second direction D2, where the third direction D3 has an oblique angle with each of the first direction D1 and the second direction D2. Each active region 120 may be disposed as a strip shape extending along a straight line, and extension directions of respective active regions 120 may be parallel to each other, and an end position of each active region 120 may be disposed to be opposite to a center position of the adjacent active region 120.

The substrate 110 may be any substrate 110 suitable for manufacturing semiconductor components, such as silicon (Si) substrate 110, epitaxial silicon (epi-Si) substrate 110, silicon-germanium (SiGe) substrate 110, silicon carbide (SiC) substrate 110, or silicon-on-insulator (Silicon-on-Insulator, SOI) substrate 110, but not limited to them. The substrate 110 includes the isolation structure 121, which is made of an insulating material, and the isolation structure 121 may be in the form of an isolation film. The isolation structure 121 may be manufactured from any of silicon oxides, silicon nitrides, silicon oxy-nitrides and a combination thereof.

In some embodiments, as shown in FIG. 7, a gate trench 135 is also provided on the substrate 110, the gate electrode 130 is located in the gate trench 135, and the gate electrode 130 includes a gate semiconductor layer 132; in addition, voids 150 are formed in the gate trench, where at least one void 150 is connected to the gate semiconductor layer 132.

In embodiments of the present application, the void is disposed in the gate trench and at least one void is connected to the gate semiconductor layer, in this way, the small size of the semiconductor structure can be ensured, while the performance of the semiconductor structure can be improved. As shown in FIGS. 1, 2 and 7, a plurality of gate trenches 135 are disposed in the substrate 110. The gate trench 135 is a structure that is disposed inside the substrate 110 in concave manner, the gate electrode 130 is disposed in the gate trench 135, and an outer wall of the gate electrode 130 is fitted with the gate trench 135 each other. A position where the substrate 110 is not provided with the gate trench 135 is defined as the active region 120. A side wall of gate trench 135 may be extended along the second direction D2, but an overall extension direction of gate trench 135 is a direct that has an included angle with the third direction D3. The gate trenches 135 may be multiple, and the depth of gate trenches 135 in the substrate 110 may be different.

In some embodiments, the gate electrode 130 includes a gate semiconductor layer 132, a gate dielectric layer 140, and a gate insulation layer 133. The gate dielectric layer 140 may be a thin film structure covering a surface of the gate trench 135, and the gate semiconductor layer 132 is located on the gate dielectric layer 140. The gate insulation layer 133 is disposed on the gate semiconductor layer 132 and is in direct contact with the gate semiconductor layer 132, and the gate semiconductor layer 132 may be doped or undoped polysilicon. A void 150 is formed inside the gate trench 135, and the void 150 may be connected with a gate semiconductor layer 132. Exemplarily, the void 150 may be located either integrally in the gate semiconductor layer 132, or partially in the gate semiconductor layer 132. At the same time, the void 150 may be one or more in number, and at least part of at least one of respective voids 150 is located in the gate semiconductor layer 132.

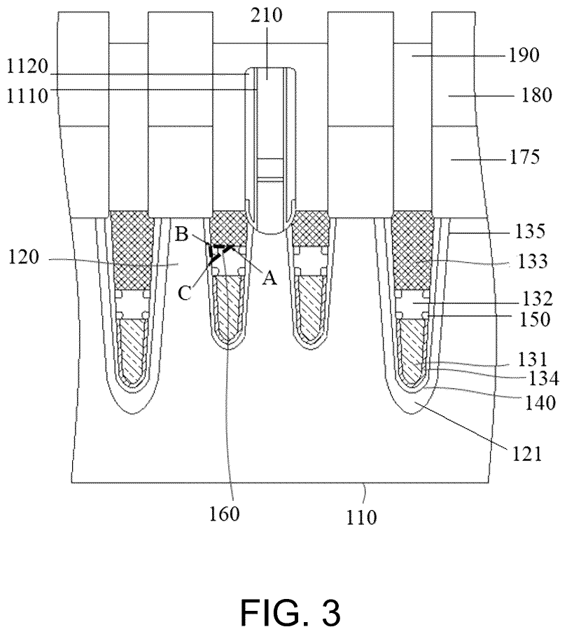

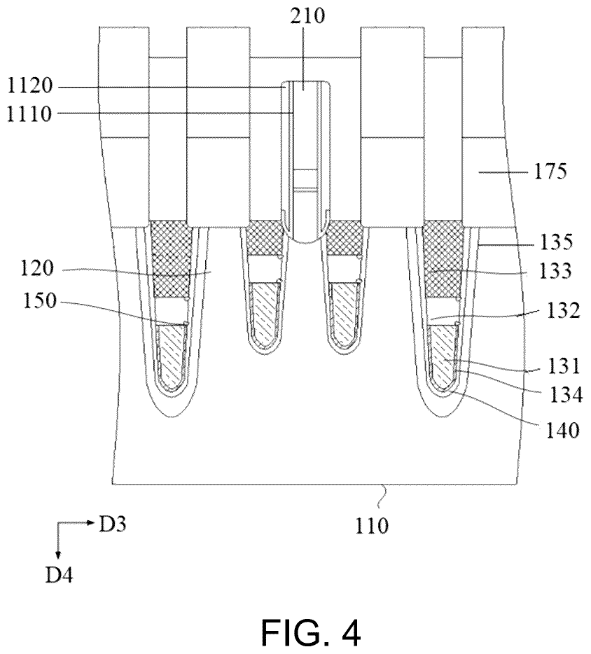

Exemplarily, the void 150 may be disposed on one side of the gate semiconductor layer 132 close to the gate insulation layer 133; alternatively, as shown in FIGS. 3 and 4, the voids 150 may be disposed on both sides of the gate semiconductor layer 132 close to the gate dielectric layer 140.

In embodiments of the present application, the performance of the semiconductor device is improved by controlling the position of the void 150 during the preparation process, thereby increasing the yield of the semiconductor structure.

In addition, as shown in FIGS. 1 and 2, the bit line 210 may include a first conductive line 214, a second conductive line 211/212, and a bit line cover film 213 that are stacked in sequence. The material of the first conductive line 214 and the second conductive line 211/212 is selected from at least one of polycrystalline silicon, titanium nitride (TiN), titanium silicon nitride (TiSiN), tungsten (W), and tungsten silicon nitride (WSiN). The bit line cover film 213 may be disposed on a second conductive line 211/212, and the bit line cover film 213 may be made of a silicon-nitride compound such as silicon nitride.

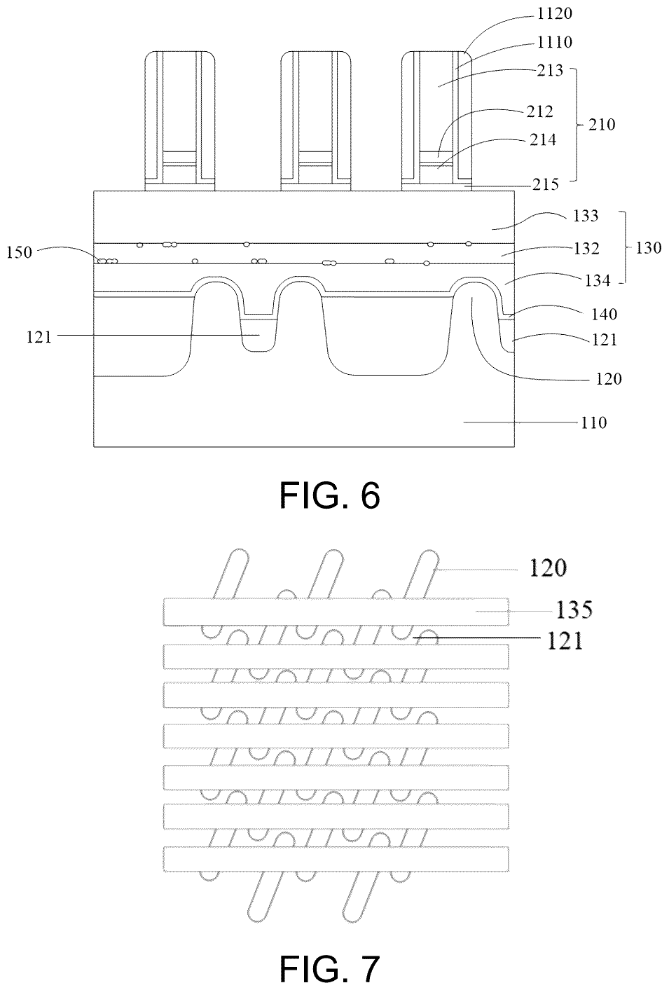

In some embodiments, as shown in FIG. 6, the bit line 210 also includes a bit line dielectric layer 215, which is located between the first conductive line 214 and the gate insulation layer 133.

In addition, as shown in FIG. 2, the semiconductor structure may also include a capacitor structure (not shown in the figure). The semiconductor structure may include a lower electrode, a dielectric film, and an upper electrode. The capacitor structure can use a potential difference generated between the lower electrode and the upper electrode to store charge inside the dielectric film. The capacitor structure also includes a landing welding layer 180 and a contact layer 175 that are arranged along the fourth direction D4 and in contact with each other. The lower electrode is in contact with the landing welding layer 180, and the contact layer 175 is in contact with the active region 120. Then, the capacitor structure may be electrically connected to the active region 120 through the landing welding layer 180 and the contact layer 175. The capacitor structure is controlled by the first conductive line 214, the second conductive line 211/212 and the gate electrode 130, and can store data. In some embodiments, the semiconductor structure 100 also includes an interlayer insulation layer 190, which may be disposed on one side of the landing welding layer 180, while the interlayer insulation layer 190 is in contact with the gate insulation layer 133. The interlayer insulation may define the landing welding layer 180 to form a plurality of separated areas. The lower electrode is in contact with the landing welding layer 180.

In some embodiments, referring to FIG. 2, the semiconductor structure also includes a spacer structure 1100, which may cover both sides of the bit line 210. The spacer structure 1100 may include a first spacer 1110 and a second spacer 1120. The first spacer 1110 may be disposed along a side wall of the bit line 210, and is contacted with the bit line 210. The second spacer 1120 is contacted with one side of the first spacer 1110 facing away from the bit line 210. The first spacer 1110 and the second spacer 1120 may be made of any of silicon oxide, silicon nitride, silicon oxy-nitride (SiON), silicon oxy-carbon nitride (SiOCN), air gap and combination thereof.

In some embodiments, as shown in FIG. 3, the gate electrode 130 also includes a gate conductive layer 131, which is disposed on a gate dielectric layer 140; the material of gate conductive layer 131 includes but is not limited to a conductive material such as tungsten, copper and silver.

In some embodiments, the gate electrode 130 also includes a barrier layer 134. The barrier layer 134 is disposed between the gate dielectric layer 140 and the gate conductive layer 131, i.e. the barrier layer 134 is disposed outside the gate conductive layer 131. Where, the gate semiconductor layer 132 is located on the barrier layer 134 and the gate conductive layer 131, and is in direct contact with the barrier layer 134 and the gate conductive layer 131. In embodiments of the present application, by setting a barrier layer 134 and making the barrier layer 134 outside the gate conductive layer 131, the metal migration in the gate conductive layer 131 can be blocked by the barrier layer 134; in addition, the adhesion between the gate conductive layer 131 and the gate dielectric layer 140 may be enhanced by the barrier layer 134, thereby improving the overall performance of the semiconductor structure.

In some embodiments, the material of gate dielectric layer 140 includes, but is not limited to, silicon oxide, silicon nitride, silicon oxy-nitride, and/or high dielectric constant materials having a higher dielectric constant than silicon oxide. The material of the gate conductive layer 131 may be selected from at least one of a metallic material, and a conductive metal nitride, for example, at least one of titanium (Ti), titanium nitride (TiN), tantalum (Ta), tantalum nitride (TaN), tungsten (W), tungsten nitride (WN), titanium silicon nitride (TiSiN), and tungsten silicon nitride (WSiN).

In addition, the material of the barrier layer 134 includes, but is not limited to, titanium nitride (TiN), or a composite layer of titanium (Ti) and titanium nitride (TiN), such as titanium/titanium nitride (Ti/TiN). The barrier layer 134 is located between the gate dielectric layer 140 and the gate conductive layer 131, so that partial or the whole outer wall of the gate conductive layer 131 is in contact with the gate dielectric layer 140 through the barrier layer 134, thereby increasing the adhesion reliability between the gate dielectric layer 140 and the gate conductive layer 131.

In some embodiments, as shown in FIG. 4, the void 150 is disposed at the position that is close to an edge of the gate semiconductor layer 132, i.e. the void 150 is disposed at the junction of the barrier layer 134 and the gate semiconductor layer 132, thereby ensuring that the overall performance of the semiconductor device is not affected by the void 150.

In some embodiments, continuing to refer to FIG. 4, the gate semiconductor layer 132 with the void 150 is in direct contact with both the barrier layer 134 and the gate conductive layer 131. In particular, a bottom of the gate semiconductor layer 132 is in direct contact with a top of the barrier layer 134 and a top of the gate conductive layer 131, thereby ensuring that the overall performance of the semiconductor device is not affected by the void 150.

To ensure that the overall performance of the semiconductor device is not affected by the void 150, in the embodiment of the present application, the void 150 is disposed in a preset area to improve the overall performance of the semiconductor device.

In some embodiments, as shown in FIGS. 2 and 3, midpoints of two adjacent sides of the gate semiconductor layer 132 (e.g., A, C) and the junction point of the two adjacent sides (e.g., B) are enclosed together to form a preset area 160, and the void 150 is disposed in the preset area 160. In this way, the void 150 is disposed in the preset area, thereby avoiding the effect of the void 150 on the performance of semiconductor device.

Exemplarily, the cutting plane of the gate semiconductor layer 132 has a plurality of sides, and a boundary line of the preset area 160 simultaneously passes through the midpoint of two adjacent sides and the junction point of two adjacent sides among the plurality of sides. The outer outline of the preset area 160 may be circular, rectangular, round-corner rectangular, etc. The preset area 160 is mainly used to determine the position of the void 150.

In some embodiments, as shown in FIGS. 2 and 3, the gate semiconductor layer 132 includes a first side and a second side, and an endpoint (B) of the first side, a midpoint (A) of the first side, and a midpoint (C) of the second side are enclosed to form a triangular area, and the triangular area forms the preset area 160.

In the embodiments of the present application, an end point of the first side may be an end point of the first side that is connected to the second side, or an end point of the first side that is away from the second side. As shown in FIGS. 2 and 3, point A is the midpoint of the first side, point B is the end point of the first side, and point C is the midpoint of the second side.

In some embodiments, as shown in FIGS. 2 and 3, the triangular area is at least partially overlapped with the gate semiconductor layer 132. Exemplarily, a part or all of the triangular area is overlapped with the gate semiconductor layer 132, and the overlapped part is an overlapping area; and at least one of the voids 150 is located in the overlapping area to avoid or improve the impact of the void 150 on the overall performance of semiconductor device.

In addition, the outline shape of the void 150 may be a ring structure formed by any curve.

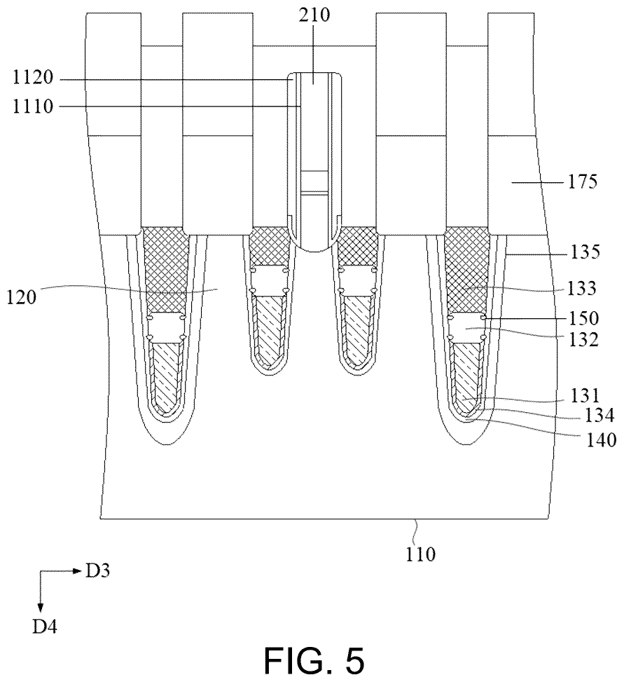

In some embodiments, referring to FIGS. 4 and 5, at least one of voids 150 is in direct contact with the gate dielectric layer 140, so that the void 150 is closer to the edge position of the gate semiconductor layer 132, thereby avoiding or improving the effect of the void 150 on the overall performance of the semiconductor device.

In embodiments of the present application, at least one of respective voids 150 is connected with a side wall of the gate dielectric layer 140. That is, the void 150 is actually formed by enclosing of the gate semiconductor layer 132 and the gate dielectric layer 140, and in fact, the void 150 is a structure formed by removing part of the outer wall of the complete gate semiconductor layer 132. And the void 150 will not pass through the gate dielectric layer 140, that is, the void 150 will not be in contact with the active region 120, so as to avoid the impact of the void 150 on the overall performance of the semiconductor device. In some embodiments, as shown in FIGS. 4 and 5, part of the void 150 is located in the gate dielectric layer 140, so that the spacing (i.e. minimum spacing) between the void 150 and the active region 120 is smaller than the spacing between the gate semiconductor layer 132 and the active region 120. In this way, the void 150 is closer to the edge of the gate semiconductor layer 132, so that the impact of void 150 on the overall performance of the semiconductor device may be avoided, and the void 150 will be not in contact with the active region 120 so as to avoid electric leakage.

In some embodiments, as shown in FIGS. 2-5, the void 150 is formed between the barrier layer 134, the gate dielectric layer 140, and the gate semiconductor layer 132, that is, the void 150 is formed at the junctions of the barrier layer 134, the gate dielectric layer 140, and the gate semiconductor layer 132, thereby avoiding the effect of the void 150 on the overall performance of semiconductor device.

Exemplarily, the barrier layer 134, the gate dielectric layer 140, and the gate semiconductor layer 132 are enclosed together to form the void 150, at this case, the void 150 may be located at the junction of the barrier layer 134 and the gate semiconductor layer 132, and the void 150 is located on an outer wall of the gate semiconductor layer 132 to achieve contact with the gate dielectric layer 140. Alternatively, the end of the void 150 may also be penetrated into the barrier layer 134 and/or the gate dielectric layer 140. Alternatively, the void 150 may be located at the position that is close to the gate semiconductor layer 132 itself and connected with the barrier layer 134 and the gate dielectric layer 140 in the gate semiconductor layer 132, but the void 150 is not in contact with the barrier layer 134 and the gate dielectric layer 140.

In some embodiments, as shown in FIGS. 4 and 5, the gate electrode 130 also includes a gate insulation layer 133, and the void 150 is formed between the gate insulation layer 133, the gate semiconductor layer 132, and the gate dielectric layer 140. The effect of the void 150 on the overall performance of the semiconductor device can be avoided by placing the void 150 at this position.

In the embodiments of the present application, the void 150 may be located at the junction of the gate insulation layer 133 and the gate semiconductor layer 132, and the void 150 may be located on the outer wall of the gate semiconductor layer 132 to achieve contact with the barrier layer 134 and the gate dielectric layer 140. Alternatively, the end of the void 150 may also be penetrated into the barrier layer 134 and/or the gate insulation layer 133. Alternatively, the void 150 may be located at the position that is close to the gate semiconductor layer 132 itself and connected with the gate insulation layer 133 and the gate dielectric layer 140 in the gate semiconductor layer 132, but the void 150 is not in contact with the gate insulation layer 133 and the gate dielectric layer 140.

In some embodiments, as shown in FIG. 5, there are arc-shaped corners between at least two adjacent sides of the gate semiconductor layer 132. Exemplarily, the cutting plane of the gate semiconductor layer 132 has multiple sides. For each pair of two adjacent sides, an arc-shaped corner is disposed at the junction of at least one pair of adjacent sides. The arc-shaped corner makes the edge of the gate semiconductor layer 132 be an arc-shaped edge, so that the adhesion between the gate semiconductor layer 132 and its adjacent material can be reduced to form the void 150, thereby avoiding the impact of the void 150 on the overall performance of the semiconductor device.

In some embodiments, the work function of the gate conductive layer 131 is greater than that of the gate semiconductor layer 132. Exemplarily, the work function of the gate conductive layer 131 may be set to 4.5 eV to 4.6 eV, and the work function of the gate semiconductor layer 132 may be set to less than 4.5 eV. More specifically, the material of the gate conductive layer 131 may include tungsten (W) with a work function of 4.5 eV; the material of the gate semiconductor layer 132 includes tungsten nitride (WN) with a work function equal to 4.3 eV.

In some embodiments, as shown in FIG. 2, at least part of the void 150 is located at the barrier layer 134 and is in direct contact with the barrier layer 134. Exemplarily, the end of the void 150 penetrates into the barrier layer 134, that is, part of the barrier layer 134 is removed. The barrier layer 134 and the gate semiconductor layer 132 are enclosed together to form the void 150, thus, the void 150 may be closer to the edge of the gate semiconductor layer 132 to avoid the effect of the void 150 on the overall performance of the semiconductor device.

In some embodiments, as shown in FIG. 2, the void 150 is also in direct contact with the gate dielectric layer 140 and the gate semiconductor layer 132. Exemplarily, the end of the void 150 simultaneously penetrates into the barrier layer 134, the gate dielectric layer 140 and the gate semiconductor layer 132. The barrier layer 134, the gate dielectric layer 140 and the gate semiconductor layer 132 are enclosed together to form the void 150. In this way, the void 150 may be closer to the edge of the gate semiconductor layer 132 to avoid the impact of the void 150 on the overall performance of the semiconductor device. When the semiconductor structure 100 provided by the present embodiment is produced, please refer to FIG. 6, the active region 120 defined by the isolation structure 121 is provided in the substrate 110, the gate trench 135 is provided in the substrate, and the gate dielectric layer 140, the barrier layer 134, the gate semiconductor layer 132, and the gate insulation layer 133 are successively deposited into the gate trench 135. It can be seen from the figure that the voids 150 are mainly distributed on both sides of the gate semiconductor layer 132, that is, at the junction between the gate semiconductor layer 132 and the barrier layer 134, and the junction between the gate semiconductor layer 132 and the gate insulation layer 133. That is, the voids 150 in the present application are mainly distributed at the edge positions of the gate semiconductor layer 132, which can avoid affecting the performance of semiconductor device.

The preparation method of semiconductor structure will be introduced in conjunction with the accompanying drawings below. Referring to FIG. 7, a plurality of isolation trenches in an array arrangement are formed in the substrate 110 by etching, and the isolation material is filled in the isolation trenches to form the isolation structure 121. The active region 120 is defined by the isolation structure 121, then the gate trench 135 is formed on the substrate 110. The gate trench 135 passes through the active region 120 and the isolation structure 121 and is extended along the second direction (D2). A plurality of gate trenches 135 are arranged at a same interval along the first direction D1, and then the gate dielectric layer (not shown in the figure) is deposited on the walls of the gate trenches 135.

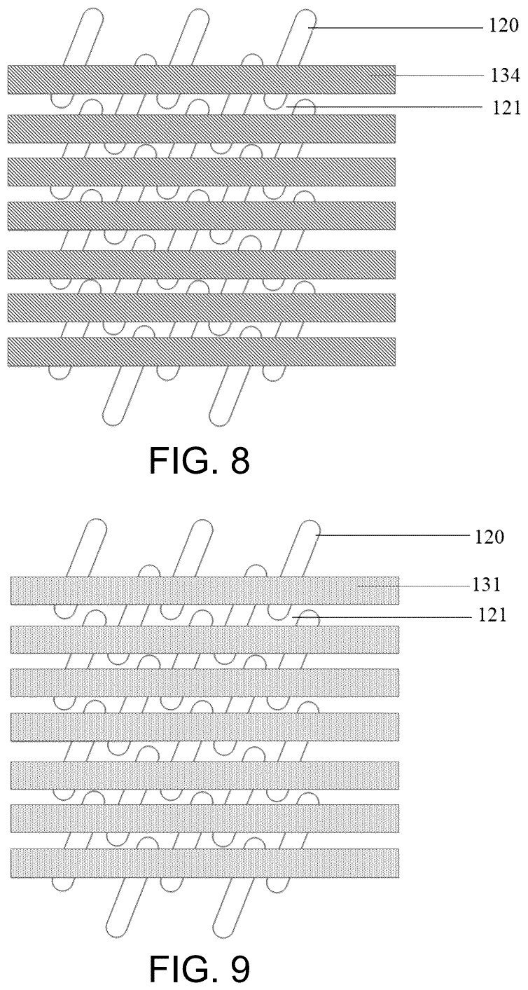

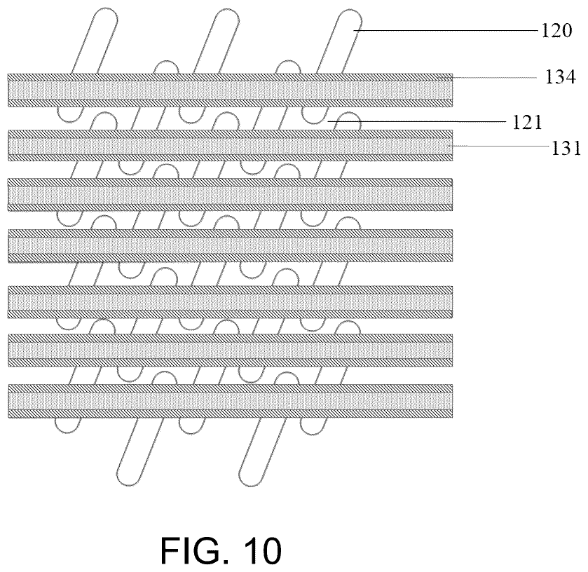

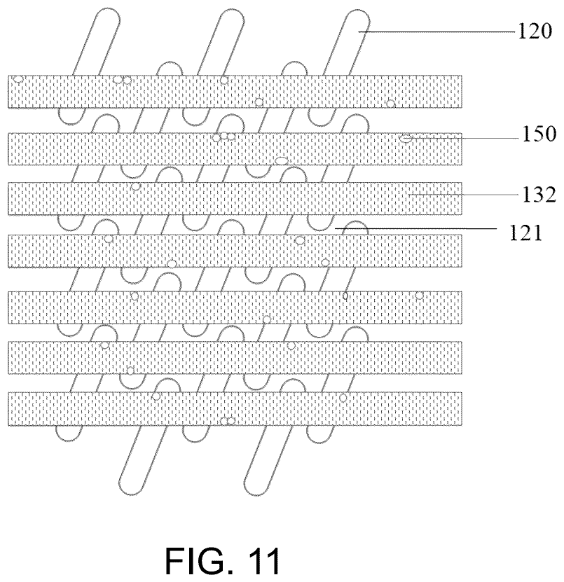

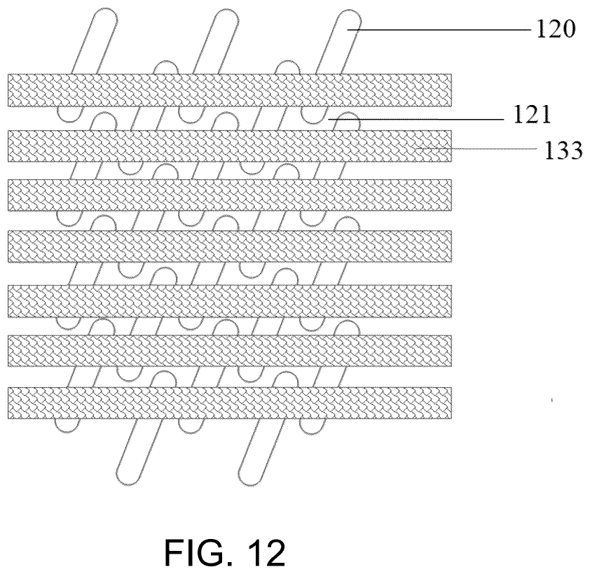

Referring to FIGS. 8 and 9, after the gate dielectric layer is formed on the walls of the gate trenches 135, the barrier layer 134 and gate conductive layer 131 are deposited on the gate dielectric layer successively. The etch-back process is performed on the barrier layer 134 and gate conductive layer 131. The remaining barrier layer 134 and gate conductive layer 131 are shown in FIG. 10, which have uneven surfaces. Further reference to FIG. 11, the gate semiconductor layer 132 is deposited on the top of the remaining barrier layer 134 and gate conductive layer 131. Through the process adjustment, there is hardly any void at the interface between the gate semiconductor layer 132 and the gate conductive layer 131 as far as possible, so that most of the voids 150 exist at the junction between the gate semiconductor layer 132 and the barrier layer 134. Then, the etch-back process is performed on the gate semiconductor layer 132, and the surface of the gate semiconductor layer 132 obtained will have grooves. Finally, referring to FIG. 12, after the gate insulation layer 133 is deposited in the gate semiconductor layer 132, since the grooves are not filled with the gate insulation layer 133, the void 150 will be formed in the end.

It can be seen that in the semiconductor structure provided by embodiments of the present application, inevitable voids are disposed in a preset area through process adjustment. For example, the voids are disposed at the edge of the gate semiconductor layer of the gate electrode, and are not in direct contact with the active region. In this way, it can be ensured that the semiconductor structure has a small size, while the influence of voids on the performance of the semiconductor device can be avoided, thereby improving the yield of the semiconductor structure.

Each embodiment or implementation in the present specification is described in a progressive manner. Each embodiment focuses on its differences from other embodiments, and the same and similar parts between respective embodiments may be referred to each other.

In the description of the present specification, the description referring to the terms “an implementation”, “some implementations”, “schematic implementations”, “examples”, “specific examples”, or “some examples”, etc., mean that specific features, structures, materials or characteristics, that are described with reference to an implementation or example, are included in at least one implementation or example of the present application. In the present specification, schematic representations of the foregoing terms do not necessarily refer to the same implementations or examples. Further, the specific features, structures, materials, or characteristics described may be combined in any one or more implementations or examples in an appropriate manner.

Finally, it should be noted that the foregoing embodiments are merely intended for illustrating the technical solutions of the present application other than limiting the present application. Although the present application is described in detail with reference to the foregoing embodiments, persons of ordinary skill in the art should understand that they may still make modifications to the technical solutions described in the foregoing embodiments or make equivalent substitutions to some or all technical features thereof, and these modifications or substitutions do not make the essence of corresponding technical solutions depart from the scope of the technical solutions of embodiments of the present application.

What is claimed is:

1. A semiconductor structure, comprising:
a substrate comprising an isolation structure and an active region defined by the isolation structure;
a gate trench disposed in the substrate;
a gate electrode located in the gate trench and comprising a gate semiconductor layer;
voids located in the gate trench, at least one of the voids being connected to the gate semiconductor layer.

2. The semiconductor structure according to claim 1, wherein the semiconductor structure further comprises a gate dielectric layer;
the gate electrode further comprises:
a gate conductive layer disposed on the gate dielectric layer;
a barrier layer disposed between the gate dielectric layer and the gate conductive layer;
wherein the gate semiconductor layer is located on the barrier layer and the gate conductive layer, and is in direct contact with the barrier layer and the gate conductive layer.

3. The semiconductor structure according to claim 1, wherein midpoints of two adjacent sides of the gate semiconductor layer and a junction point of the two adjacent sides are enclosed together to form a preset area.

4. The semiconductor structure according to claim 3, wherein the gate semiconductor layer comprises a first side and a second side; and an end point of the first side, and a midpoint of the first side and a midpoint of the second side as end points are enclosed to form a triangular area, the triangular area forming the preset area.

5. The semiconductor structure according to claim 4, wherein the triangular area is at least partially overlapped with the gate semiconductor layer, and at least one of the voids is located in an overlapping area.

6. The semiconductor structure according to claim 2, wherein at least one of the voids is in direct contact with the gate dielectric layer.

7. The semiconductor structure according to claim 6, wherein the at least one of the voids is partially located in the gate dielectric layer, so that a minimum spacing between the void and the active region is less than a spacing between the gate semiconductor layer and the active region.

8. The semiconductor structure according to claim 2, wherein the voids are formed among the barrier layer, the gate dielectric layer and the gate semiconductor layer.

9. The semiconductor structure according to claim 2, wherein the gate electrode further comprises a gate insulation layer, and the voids are formed between the gate insulation layer, the gate semiconductor layer and the gate dielectric layer.

10. The semiconductor structure according to claim 1, wherein an arc-shaped corner is disposed between at least two adjacent sides of the gate semiconductor layer.

11. The semiconductor structure according to claim 2, wherein a work function of the gate conductive layer is greater than a work function of the gate semiconductor layer.

12. The semiconductor structure according to claim 2, wherein at least part of the voids is located on the barrier layer, and is in direct contact with the barrier layer.

13. The semiconductor structure according to claim 12, wherein the voids are further in direct contact with the gate dielectric layer and the gate semiconductor layer.
